(19) United States
(12) Patent Application Publication
(10) Pub. No.: US 2005/0251839 A1
(43) Pub. Date: Nov. 10, 2005

(54) Dual tuner

(75) Inventor: Shigetomo Chiba, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/121,422

(22) Filed: May 4, 2005

(30) Foreign Application Priority Data
May 6, 2004 (JP) 2004-137402

(51) Int. Cl. H04N 7/173; H04N 5/50; H04N 5/44; H04N 7/16; H03B 1/00

(52) U.S. Cl. 725/100; 725/131; 725/139; 725/151; 348/725; 348/731; 331/46

(57) ABSTRACT

A dual tuner is described that includes a rectangular parallelepiped casing having four side plates, partitions for dividing inside of the casing into a plurality of areas, a coaxial connector fitted to one side plate of the casing, and a circuit board mounted in the casing. Both a data tuner and a video tuner are divided by the partitions. The signal line of the data tuner which has severe spurious interference standard requirements, is set noticeably shorter than the signal line of the video tuner whose spurious interference standard requirements are not so severe.

### BACKGROUND OF THE INVENTION

1. Field of the Invention

The present invention relates to a dual tuner in which a tuner serving as a cable modem and a tuner serving as a cable television receiver are mounted in a common casing.

2. Description of the Related Art

Either a data tuner for a cable modem or a video tuner for receiving cable television signals is connected to cable lines employed in a CATV system. The data tuner for a cable modem is similar to the video tuner for receiving cable television signals in its configuration, while an up-stream circuit is incorporated into the data tuner which a data can be sent or received (for example, see Japanese Unexamined Patent Application Publication No. 10-215148 (pages 3 to 7, FIG. 8)). Further, severe spurious interference standard requirements are needed to reduce adverse influence due to the interference caused by spurious signals (signals except a target signal).

Conventionally, the data tuner for a cable modem and the video tuner for receiving cable television signals are incorporated in separate casings, respectively and then are housed in a setup box.

### SUMMARY OF THE INVENTION

As described above, there is a problem in that it is difficult to have a compact setup box receiving both the data tuner for a cable modem and the video tuner for receiving cable television signals, since conventionally each of the data tuner for a cable modem and the video tuner for receiving cable television signals are incorporated into the separate casings respectively. Accordingly, in order to improve the space factor, a dual tuner integrally formed by incorporating the data tuner and the video tuner into the same casing is considered. However, in this case, the performance of the dual tuner is deteriorated due to mutual interference of the data tuner and the video tuner or severe spurious interference standard requirements applied to the data tuner are not satisfied. Therefore, special consideration is needed.

The present invention was made in consideration of the above-mentioned problems, and it is an object of the present invention to provide a dual tuner in which a space factor is improved by incorporating the data tuner and the video tuner into a same casing without deteriorating performances of both the data tuner for a cable modem and the video tuner for receiving cable television signals.

In order to achieve the above object, the present invention is directed for a dual tuner including a rectangular parallelepiped casing having four side plates, partitions for dividing inside of the casing into a plurality of areas, a coaxial connector fitted to one side plate of the casing, and a circuit board, which is mounted in the casing, having a first tuner and a second tuner. The first tuner is a data tuner for a cable modem having an up-stream circuit, the second tuner is a video tuner for receiving cable television signals which does not have the up-stream circuit, and the first tuner and the second tuner are spaced apart each other by one of the partitions. The wiring length from an input terminal of the first tuner to the coaxial connector is shorter than the wiring length from an input terminal of the second tuner to the coaxial connector.

In the dual tuner to be configured as described above, a signal line of the data tuner (the first tuner) with the severe spurious interference standard requirement is short in length, whereby it is possible to avoid an adverse influence due to an interference of the spurious signal as much as possible. Accordingly, the data tuner maintains a steady operating state. In the meantime, since the signal line of the video tuner (the second tuner) is relatively long, the signal line of the video tuner may be influenced by a signal produced by a local oscillation circuit of the data tuner. However, the spurious interference standard requirements of the video tuner are not so much severe, and there is a slight possibility of mis-operation of the video tuner due to an interference of spurious signals caused by the data tuner. As a result, by incorporating the data tuner and the video tuner into a same casing, it is possible to improve a space factor without deteriorating performances of both the data tuner and the video tuner.

In the dual tuner having such construction, it is preferable that the first tuner have a double conversion structure including two local oscillation circuits and two mixers, and an oscillating frequency of the local oscillation circuit is set out of a reception band, thereby improving the performance of the data tuner as well as performance of the video tuner.

Further, in the dual tuner of the above mentioned construction, it is desirable that the input terminal of the first tuner and the input tuner of the second tuner are arranged to face the same side plate, because the signal line of the video tuner becomes shortened to thereby reduce an adverse influence due to an interference of the spurious signals.

In the dual tuner according to an aspect of the present invention, the signal line of the data tuner for a cable modem is short in length to avoid an adverse influence due to interference of the spurious signals. This in turn allows the data tuner to maintain a steady operating stage. Furthermore, in the video tuner for receiving cable television signals, there is a small amount of an adverse influence due to interference of the spurious signals even when the signal line is relatively long in length. In particular, when the data tuner has a double conversion structure including two local oscillation circuits and two mixers, the spurious signals caused by the data tuner can hardly influence on an operation of the video tuner. Therefore, it is possible to provide a dual tuner having an improved space factor by incorporating the data tuner and the video tuner into a same casing without deteriorating performances of both the data tuner and the video tuner.

### BRIEF DESCRIPTION OF THE DRAWINGS

FIG. 1 is an explanatory view schematically illustrating a circuit layout of a dual tuner according to a first embodiment of the present invention;

FIG. 2 is an explanatory view schematically illustrating a circuit layout of a dual tuner according to a second embodiment of the present invention;

FIG. 3 is an explanatory view schematically illustrating a circuit layout of a dual tuner according to a third embodiment of the present invention; and

FIG. 4 is an explanatory view schematically illustrating a circuit layout of a dual tuner according to a fourth embodiment of the present invention.

### DESCRIPTION OF THE PREFERRED EMBODIMENT

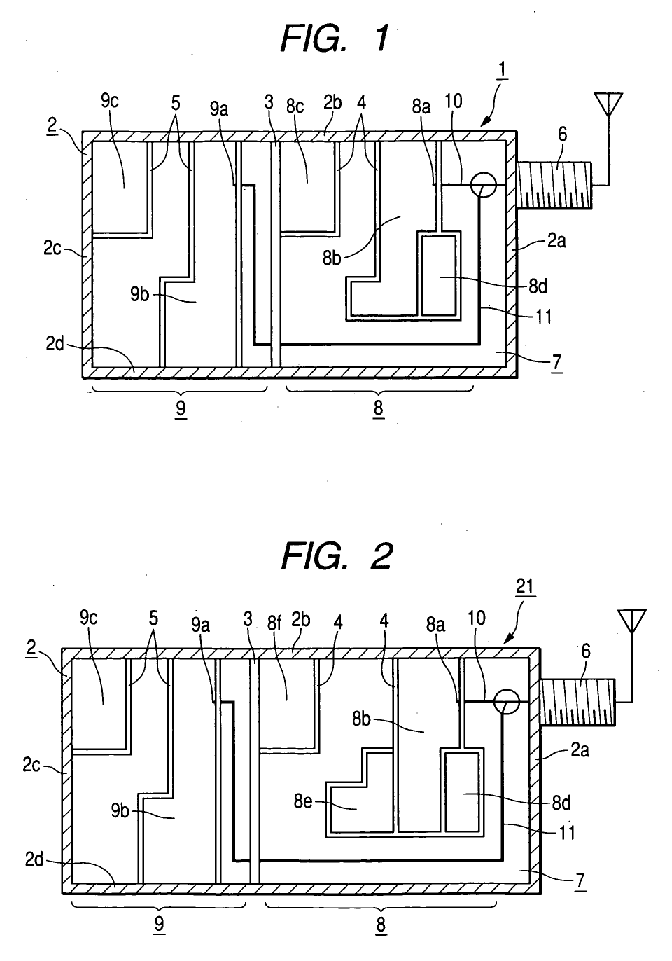

Preferred embodiments of the present invention will now be described with reference to the drawings. FIG. 1 is an explanatory view schematically illustrating a circuit layout of a dual tuner according to a first embodiment of the present invention. The dual tuner 1 shown in FIG. 1 is accommodated in a setup box not shown in the drawings to be connected to a cable circuit in a CATV system, and operates as a tuner serving as a cable modem and a cable television receiver.

The dual tuner 1 mainly includes a rectangular parallelepiped casing 2 having four side plates 2a, 2b, 2c, 2d, partitions 3, 4, 5 for dividing inside of the casing 2 into a plurality of areas, a coaxial connector 6 fitted to one side plate 2a of the casing 2, and a circuit board 7 mounted in the casing 2, a data tuner 8 for a cable modem and a video tuner 9 for receiving cable television signals are mounted on a circuit board 7.

The casing 2 is made of a metallic plate, and has a chassis portion which is formed in a box shape having a bottom, side plates 2a through 2d formed therein, and a top plate (not shown in the drawings) which covers inside of the chassis portion. A plurality of the partitions 3 to 5 are also made of a metallic plate, and the size or shape of the individual partitions 3 to 5 is determined depending upon necessity of a sealing effect or limitation of a conductor pattern. The coaxial connector 6 is securely attached to the side plate 2a by means of caulking or the like, and a coaxial cable not shown in the drawings is connected to the coaxial connector 6. A variety of electronic parts are mounted on a conductor pattern of the circuit board 7, a circuit forming the data tuner 8 is provided at the right side, in the drawing, of the partition 3 located at nearly the center, and another circuit forming the video turner 9 is provided at the left side, in the drawing, of the partition 3. That is, both the data tuner 8 and the video tuner 9 are divided by the partition 3, and a distance from an input terminal 8a of the data tuner 8 to the coaxial connector 6 is set to be remarkably shorter than a distance from an input terminal 9a of the video tuner 9 to the coaxial connector 6.

The data tuner 8 for a cable modem includes, in an individual areas divided by a plurality of partitions 5, a band pass filter unit 8b allowing a desired signal to pass through, a frequency conversion circuit unit 8c converting the reception signal passing through the filter unit 8b into an intermediate frequency signal, an up-stream circuit unit 8d for transmission, and an amplifying unit not shown in the drawings. The frequency conversion circuit unit 8c is provided with a local oscillation circuit and a mixer. The input terminal 8a of the data tuner 8 is connected to the coaxial connector 6 by means of a signal line 10.

The video tuner 9 for receiving cable television signals includes, in an individual areas divided by a plurality of partitions 5, a band pass filter unit 9b allowing a desired signal to pass through, a frequency conversion circuit unit 9c converting the reception signal passing through the filter unit 9b into an intermediate frequency signal, and an amplifying unit not shown in the drawings. The frequency conversion circuit unit 9c is provided with a local oscillation circuit and a mixer. The input terminal 9a of the video tuner 9 is connected to the coaxial connector 6 by means of a signal line 11 extended roundabout the data tuner 8.

As described above, in the dual tuner 1 according to the present embodiment, an adverse influence due to interference caused by the spurious signals is suppressed as much as possible, since the signal line 10 of the data tuner 8 to which severe spurious interference standard requirements are applied is considerably shortened in length. Accordingly, the data tuner 8 always maintains a steady operating state. Further, the signal line 11 is extended to bypass the data tuner 8, whereby the video tuner 9 may be adversely influenced by a signal produced by a local oscillation circuit of the data tuner 8. However, the spurious interference standard requirements of the video tuner 9 are not so much severe, and thus there is a low possibility that the video tuner 9 is mis-operated due to an interference of spurious signals caused by the data tuner 8. More specifically, in this embodiment, a circuit layout in which performance of the data tuner 8 and performance of the video tuner 9 are not deteriorated is employed. Further, it is possible to provide the dual tuner 1 with an improved space factor and high reliability by incorporating the individual tuners 8 and 9 into the common casing 2.

FIG. 2 is an explanatory view schematically illustrating a circuit layout of a dual tuner according to a second embodiment of the present invention, the parts corresponding to FIG. 1 will be designated by the same reference numerals, and detailed description thereof will be omitted.

The dual tuner 21 shown in FIG. 2 includes a first frequency conversion circuit unit 8e for converting the reception signal passing through the band pass filter 8b into a first intermediate frequency signal, a second frequency conversion circuit 8f for converting the first intermediate frequency signal into a second intermediate frequency signal. The difference between the dual tuner 21 and the dual tuner 1 according to the first embodiment as mentioned above is that the oscillating frequency of the local oscillation circuit provided in the first frequency conversion circuit 8e and the second frequency conversion circuit 8f is set out of a reception band. That is, the data tuner 8 of the dual tuner 21 according to this embodiment has a double conversion structure including two local oscillation circuits and two mixers, and the local oscillation circuit (a variable frequency oscillation circuit) arranged in the first frequency conversion circuit unit 8e is variably set so that an oscillation frequency is, for example, 1 GHz higher than a tuning frequency. Accordingly, this conversion circuit 8e causes the reception signal to be converted into an intermediate frequency signal which is 1 GHz higher than the tuning frequency. Moreover, the local oscillation circuit (a fixed frequency oscillation circuit) arranged in the second frequency conversion circuit unit 8f is variably set so that an oscillation frequency is, for example, 1 GHz higher than a general intermediate frequency. Therefore, by the conversion circuit unit 8f, the first intermediate frequency signal is converted into a general intermediate frequency signal (the second intermediate frequency signal). Thus, either the oscillation frequency of the local oscillation circuit arranged in the first frequency conversion circuit unit 8e or the oscillation frequency of the local oscillation circuit arranged in the second frequency conversion circuit unit 8f is considerably deviated from the reception band. In the dual tuner 21, the performance of the data tuner 8 can be improved, and further, an adverse influence on operation of the video tuner 9 due to spurious signals caused by the data tuner 8 can be avoided. Consequently, this leads to an improved performance of the video tuner 9.

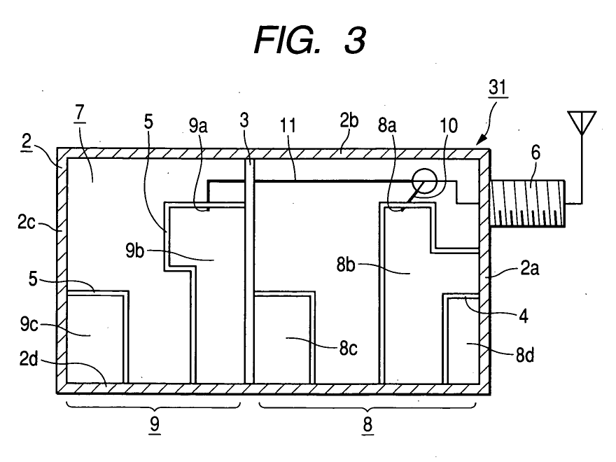

FIG. 3 is an explanatory view schematically illustrating a circuit layout of a dual tuner according to a third embodiment of the present invention, the parts corresponding to FIG. 1 will be designated by the same reference numerals, and detailed description thereof will be omitted.

A difference between a dual tuner 31 shown in FIG. 3 and the dual tuner 1 according to the first embodiment previously mentioned is that the dual tuner 31 has both the input terminal 8a of the data tuner 8 for a cable modem and the input terminal 9a of the video tuner 9 for receiving cable television signals which are arranged so as to face the side plate 2b of the casing 2, whereby the signal line 11 of the video tuner 9 can be shortened. More specifically, a circuit layout that both the input terminal 8a of the tuner 8 and the input terminal 9a of the tuner 9 face the same side plate 2b is employed, whereby the signal line 11 of the video tuner 9 is arranged in a relatively short route which does not bypass the data tuner 8. Therefore, mis-operation of the video tuner 9 due to an interference of spurious signals caused by the data tuner 8 can be avoided. As. a consequence, the performance of the video tuner 9 can be improved comparing to the dual tuner 1.

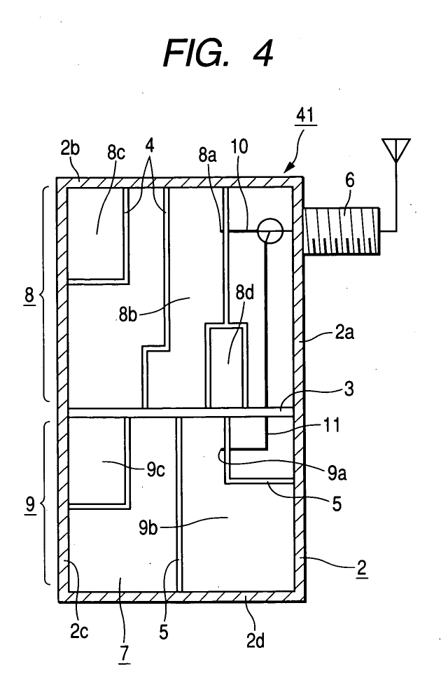

FIG. 4 is an explanatory view schematically illustrating a circuit layout of a dual tuner according to a fourth embodiment of the present invention, the parts corresponding to FIG. 1 and FIG. 3 will be designated by the same reference numerals, and detailed description thereof will be omitted.

The dual tuner 41 shown in FIG. 4A is a modification of the dual tuner 31 described in the third embodiment mentioned above. The main difference between the dual tuner 41 and the dual tuner 31 is that the dual tuner 41 has both the input terminal 8a of the tuner 8 and the input terminal 9a of the tuner 9 which are arranged so as to face the side plate 2a instead of the side plate 2b. More specifically, in the first to third embodiments, the casing 2 is in the form of a horizontal rectangular parallelepiped in which side plates 2b, 2d are longer than the vertical side plates. However, in the dual tuner 41 shown in FIG. 4, the casing 2 is in the form of an elongated rectangular parallelepiped in which the vertical side plates 2a, 2b are longer than the side plates. Therefore, in the above dual turner 41, the input terminal 8a of the data tuner 8 and the input terminal 9a of the video tuner 9 are arranged so as to face the side plate 2a with the coaxial connector 6 fitted thereto. In the dual tuner 41 in which the above mentioned circuit layout is employed, in a manner similar to the dual tuner 31, the signal line 11 of the video tuner 9 is arranged in a relatively short route which does not bypass the data tuner 8. Therefore, mis-operation of the video tuner 9 due to an interference of spurious signals caused by the data tuner 8 can be avoided. As a result, it may be expected that performance of the video tuner 9 is improved.

1. A dual tuner comprising:
a rectangular parallelepiped casing having four side plates;
partitions for dividing an inside of the casing into a plurality of areas;
a coaxial connector fitted to one side plate of the casing; and
a circuit board which is mounted in the casing and has a first tuner and a second tuner,
wherein the first tuner is a data tuner for a cable modem having an up-stream circuit, the second tuner is a video tuner for receiving cable television signals which does not have the up-stream circuit, the first tuner and the second tuner are spaced apart each other by one of the partitions, a wiring length from an input terminal of the first tuner to the coaxial connector is shorter than a wiring length from an input terminal of the second tuner to the coaxial connector.

2. The dual tuner according to claim 1, wherein the first tuner has a double conversion structure including two local oscillation circuits and two mixers, and an oscillating frequency of the local oscillation circuit is set out of a reception band.

3. The dual tuner according to claim 1, wherein the input terminal of the first tuner and the input tuner of the second tuner are arranged so as to face the same side plate.
